(19) United States
(12) Patent Application Publication
(10) Pub. No.: US 2019/0064241 A1
(43) Pub. Date: Feb. 28, 2019

(54) THERMOCHROMIC CONTAINER FOR ELECTROMAGNETIC RADIATION PROTECTION

(71) Applicant: Labcon, North America, Petaluma, CA (US)

(72) Inventors: Thomas Moulton, San Francisco, CA (US); Scott Weitze, Alameda, CA (US)

(73) Assignee: Labcon, North America, Petaluma, CA (US)

(21) Appl. No.: 15/685,223

(22) Filed: Aug. 24, 2017

(51) Int. Cl. G01R 29/08; G01F 23/284; G02F 1/01; G01K 11/12; G01K 3/04; G01K 11/20; G01K 11/00; B41M 5/28; B05D 5/06

(52) U.S. Cl. CPC G01R 29/0842; G01F 23/284; G02F 1/0147; G01K 11/125; B05D 5/06; G01K 11/20; G01K 11/006; B41M 5/282; G01K 3/04

(57) ABSTRACT

A container is disclosed which may be used with fluids sensitive to light of one or more known wavelengths. The container may be formed of a thermochromic material or including a thermochromic coating. The properties of the thermochromic material or coating may be selected so as to be transparent to light of the wavelength to which the fluid is sensitive at a first temperature and to be opaque to that wavelength of light at a second temperature. While a technician is handling the container, the container is controlled to be at the first temperature. When the technician is finished, the container is controlled to move to the second temperature to protect the fluid within the container.

### BACKGROUND

Capped containers, such as tubes, vials, bottles and cups, are often used to collect, store, and transport fluids and other materials. These materials may include biological and other specimens which may be sensitive to electromagnetic radiation from visible, UV and other wavelengths of the electromagnetic spectrum. This sensitivity may result in the specimen degrading or otherwise chemically altering within the container upon being exposed to light of certain frequencies.

Thermochromic containers are known which change color when at a certain temperature. Such containers have been used as temperature indicators of the fluid within the container.

### SUMMARY

The present technology relates to a thermochromic container which is transparent at a first temperature range, such as for example at room or skin temperature, but opaque to predefined wavelengths of light at a second temperature range. In one example, the thermochromic container is transparent at skin temperature so that the container may be transparent when in use by a technician adding or subtracting a fluid from the thermochromic container. Thus, the technician may view the contents of the container as well as how much is in the container. When the technician finishes handling the container, the container may change color and turn opaque to prevent light of predefined wavelengths from passing through the container to the contents within.

In embodiments, the present technology relates to container for holding a fluid, the container comprising: a wall comprising a thermochromic material transmitting a wavelength of light to which the fluid is sensitive when the container is at a first temperature, and the thermochromic material blocking the wavelength of light when the container is at a second temperature.

In further embodiments, the present technology relates to a container for holding a fluid, the container comprising: a wall comprising a thermochromic material configured to allow visual inspection of the fluid within the container when the container is at a first temperature, and configured to block a wavelength of light to which the fluid is sensitive when the container is at a second temperature.

In another embodiment, the present technology relates to a container for holding a fluid, the container comprising: a wall comprising a thermochromic material configured to transmit a predefined wavelength of light to which the fluid is sensitive to allow visual inspection of the fluid within the container when the container is manipulated in a human hand to bring the container to a first temperature by manipulation of the container in a human hand, and the thermochromic material configured to block the wavelength of light to which the fluid is sensitive when the container is not at the first temperature.

In a further embodiment, the present technology relates to a method of working with a fluid within a container in a laboratory, the fluid sensitive to a wavelength of light, the method comprising the steps of: (a) controlling a temperature of the container to bring the container to a first temperature at which a thermochromic material of the container is clear; (b) visually inspecting the fluid and/or an amount of fluid within the container while the container is controlled to be at the first temperature; and (c) controlling a temperature of the container to bring the container to a second temperature at which the thermochromic material of the container is opaque to the wavelength of light to which the fluid is sensitive.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 illustrates a view of a container according to embodiments of the present technology.

FIG. 2 illustrates a view of a container including a cap and specimen according to embodiments of the present technology.

FIG. 3 illustrates a view of a container having changed color according to embodiments of the present technology.

FIGS. 4-6 illustrate views of three containers for blocking three different wavelengths of light.

FIG. 7 illustrates a view of a container having partially changed color according to embodiments of the present technology.

FIG. 8 illustrates a view of a container having partially changed color according to further embodiments of the present technology.

### DETAILED DESCRIPTION

The present technology, roughly described, relates to a container for holding a fluid sensitive to certain wavelengths of the electromagnetic spectrum. The container may be formed of a thermochromic material or including a thermochromic coating. The properties of the thermochromic material or coating may be selected so as to be transparent to light of the wavelengths to which the fluid is sensitive at a first temperature, and to be opaque to those wavelengths of light at a second temperature. In one embodiment, the first temperature may be the temperature of human skin. Thus, while a technician is handling the container, the container is transparent. In this condition, the technician can easily examine the contents of the container, such as for example viewing properties of the fluid in the container and how much of the fluid is in the container. When the technician is finished handling the container, it may turn a color so as to be opaque or otherwise block wavelengths of light known to be harmful to the contents of the container.

In a further embodiment, the thermochromic material may be chosen so as to be transparent at room temperature (or other temperature of a room in which a technician is working with the container). Thus, while the technician is working in the room with the container, the container is transparent. When the technician is finished with the container, the technician may move the container to second location (colder or warmer than the first location) where the container may turn a color so as to be opaque or otherwise block wavelengths of light known to be harmful to the contents of the container.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal” as may be used herein are by way of example and illustrative purposes only, and are not meant to limit the description of the invention inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.25%.

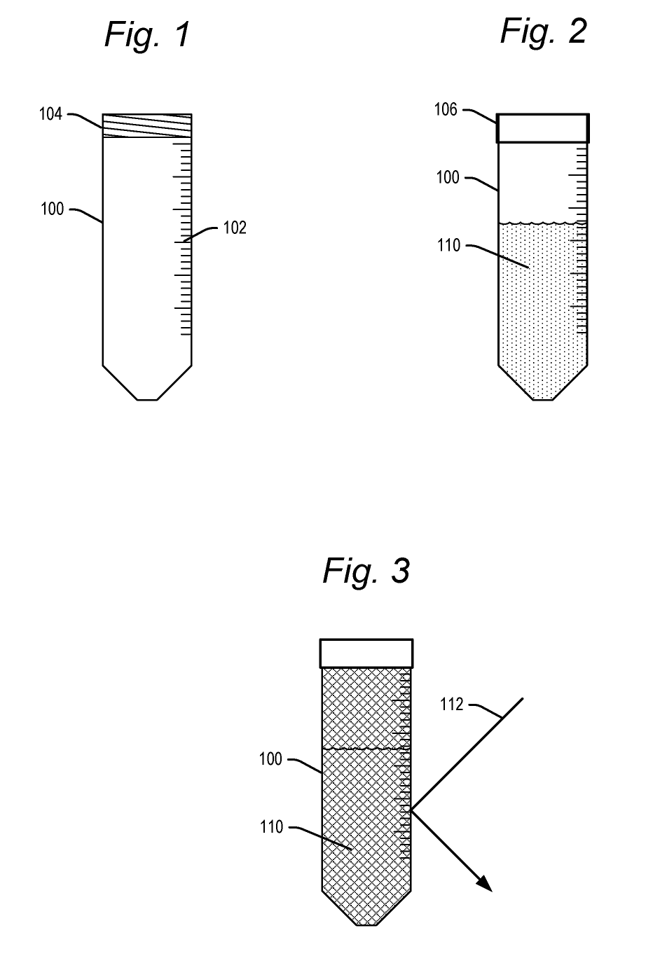

FIG. 1 shows a container 100 according to embodiments of the present technology. Container 100 may for example be a centrifuge tube, a micro-centrifuge tube or a pipette tip, but in general, container 100 may be any of a variety of tubes, vials, bottles and cups. While the figures show a cylindrical container have a particular length and diameter, it is understood that non-cylindrical containers, and containers of other lengths and diameters, may be used in further examples. In embodiments, the container 100 may include lines 102 providing an indicator of the volumetric fill of container 100. Lines 102 may be omitted in further embodiments. The container 100 may further include threads 104 for receiving a cap 106 (FIG. 2) to provide a hermetic seal of the container 100. The threads 104 may be omitted in further embodiments. For example, the container 100 may alternatively be configured so that the cap 106 snaps on to the container 100. In further embodiments, container 100 may be configured to operate without cap 106.

Container 100 may be used to collect, store and/or transport fluids and other materials. FIG. 2 illustrates the container 100 including a fluid 110 sealed within the container by cap 106. Fluid 110 may be a specimen for laboratory analysis, though it may be other types of specimens in further examples. In embodiments, fluid 110 may have a sensitivity to one or more wavelengths of the electromagnetic spectrum. Such fluids may include for example various fluorescent proteins, fluorophores and other chemical compounds. Such compounds within the fluid 110 may break down or may otherwise become chemically altered when exposed to certain types of electromagnetic radiation over a period of time. Such electromagnetic radiation may include light in the visible spectrum, ultraviolet (UV) light, infrared (IR) light, fluorescent wavelengths of light and other wavelengths from the electromagnetic spectrum. While the container 100 may advantageously be used with fluids 110 that are sensitive to light, it is understood that container 100 may also be used with fluids 110 that are not sensitive to light.

In accordance with aspects of the present technology, container 100 may include thermochromic material which changes color at different temperatures. In one example, the walls forming the container 100 may be formed of thermochromic material, such as for example plastic or glass laced with thermochromic ink or other compound. In a further embodiment, a thermochromic ink or other compound may be applied as a film onto the walls of the container 100. Thermochromic inks and compounds are known, but in general, may for example include thermochromatic liquid crystals (TLCs) and leuco dyes. Leuco dye inks may be preferably given their durable chemistry, but either TLCs or leuco dyes may be used.

The properties of the thermochromic material in container 100 may be selected so as to be transparent or translucent at a first temperature or temperature range, and to be opaque at a second temperature or temperature range. In one embodiment, the first temperature (at which the container 100 is transparent or translucent) may be human skin temperature at about 37° C. (plus or minus a few degrees). The second temperature may be room temperature (about 23° C. plus or minus a few degrees), or temperatures in general other than the first temperature.

In such an example, manipulation of the container 100 by a technician will bring the container 100 (at least those parts handled by the technician) to skin temperature, thus making those parts of the container 100 transparent or translucent. In this state, the technician can add or remove fluid from the container 100, and visually examine the fluid 110 within the container 100 to inspect its visible properties and how much is in the container. Once the technician is done, he or she releases the container 100, at which point the container moves toward the second temperature. Once at the second temperature, the container changes color, for example to brown or some other color, as shown for example in FIG. 3. In this state, the container 100 is opaque, blocking some or all wavelengths of light 112 from reaching the fluid 110 within the container 100, and thus preserving the integrity of the fluid 110.

The first and second temperatures set forth above are by way of example only, and may be varied in further embodiments. For example, in one further embodiment, the first temperature at which container 100 may be transparent or translucent may be room temperature, plus or minus a few degrees. And the second temperature may cooler or warmer than room temperature by at least a few degrees. In such an embodiment, the technician can add or remove fluid 110 from the container 100, and visually examine the fluid 110 and how much is in the container 100 while working at room temperature. Thereafter, the container 100 may be stored or transported at a temperature other than room temperature. Once at the second temperature other than room temperature, the container 100 will change color so as to be opaque, blocking some or all wavelengths of light from reaching the fluid 110 within the container 100, and thus preserving the integrity of the fluid 110. It is understood that the first and second temperatures at which the container 100 is transparent/translucent and opaque, respectively may vary beyond those temperatures described above.

The thermochromic material used in container 100 may be such that it can repeatably switch between transparent/translucent and opaque upon cycling between the first and second temperatures. Thus, a technician may quickly, easily and repeatably change the color of container 100 from opaque to transparent or translucent whenever the technician wishes to inspect or work with the fluid 110 within the container 100.

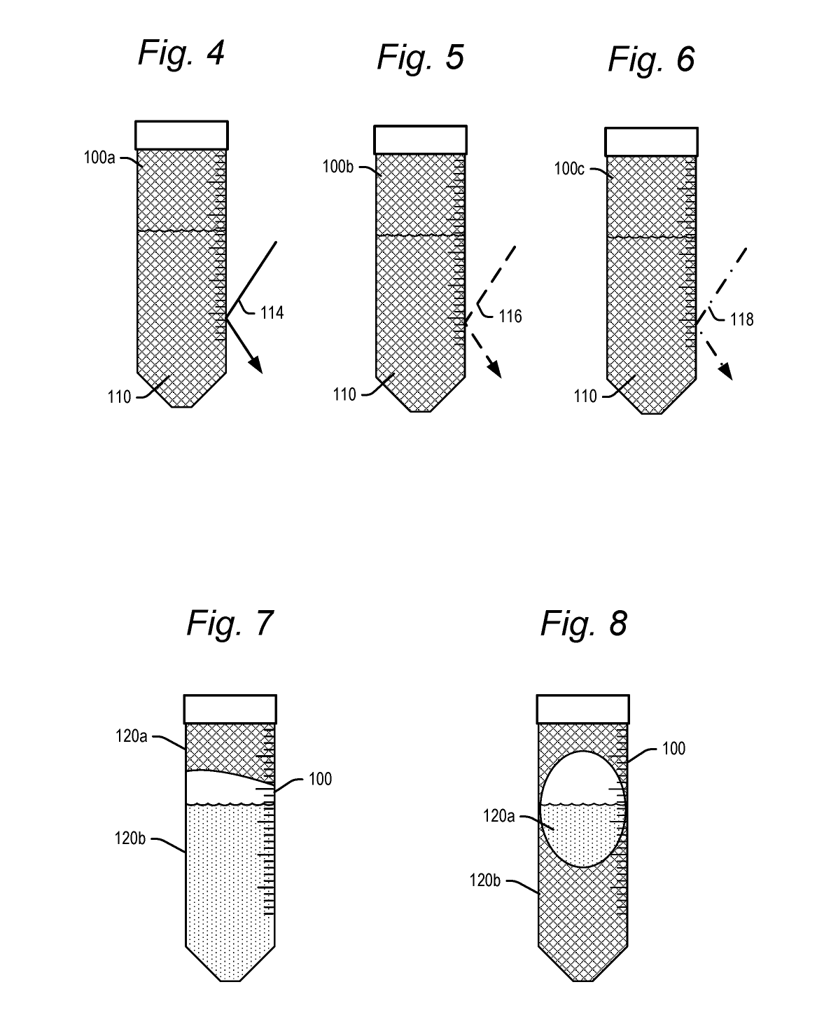

Different fluids may be sensitive to different wavelengths of light. As such, container 100 may be customized with a thermochromic material of a particular composition so as to be opaque to a certain wavelength or wavelengths of light to which the fluids to be used within the container 100 are sensitive. For example, where a particular fluid 110 to be used within container 100 is sensitive to light in the visible spectrum, a thermochromic material may be selected which is opaque (at the second temperature) to visible light. On the other hand, where a particular fluid 110 to be used within container 100 is sensitive for example to UV light, the thermochromic material may be selected which is opaque (at the second temperature) to UV light. Thus, different containers 100 can be designed to work with different fluids 110. FIGS. 4-6 show three different containers 100a, 100b and 110c configured to block three different wavelengths of light, 114, 116 and 118, respectively. Thus, when working with a fluid sensitive to the first wavelength of light 114, the first container 100a may be used. When working with a fluid sensitive to the second wavelength of light 116, the second container 100b may be used. When working with a fluid sensitive to the third wavelength of light 116, the third container 100c may be used. It is possible that these different containers 100a-c can be different colors when the thermochromic material is opaque so as to distinguish between the different containers.

A container 100 may be “tuned” to block a predefined wavelength or predefined wavelengths of light in a known manner when opaque at the second temperature. Similarly, different containers 100 may be tuned to block different wavelengths in a known manner when opaque at the second temperature. In one example, a container 100 may be formed with a thermochromic material, and then tested to see which wavelengths of light are blocked when the container 100 is opaque. In further embodiments, the container 100 may be formed with a thermochromic material which is known to block certain wavelengths of light when opaque. Thus, when a fluid 110 to be used within container 100 is known to be sensitive to certain wavelengths of light, a technician may choose a container 100 which is known to block those wavelengths of light when opaque.

In an embodiment where the container 100 is opaque to UV light, the container 100 may allow light in the visible spectrum to pass through. Thus, the container 100 may be opaque to certain wavelengths while still being transparent. In general, the container will transmit one or more selected wavelengths light (to which a fluid is sensitive) at the first temperature, and block those one or more selected wavelengths of light at the second temperature.

In the embodiment shown in FIG. 3, the entire container 100 is opaque and blocking light 112 of at least certain wavelengths. It is conceivable that portions of the container be at the second temperature and thus opaque, while other portions of the container be at the first temperature and thus transparent or translucent. Such embodiment are shown for example in FIGS. 7 and 8. In FIG. 7, a technician may for example grip a bottom portion 120a of the container 100 in his or her hand so that the bottom portion 120a becomes clear, while a top portion 120b of container 100 remains opaque. In FIG. 8, a technician may for example press their thumb against a portion 120a of container 100, thus rendering the portion 120a of the container 100 in contact with the user's thumb clear, while other portions 120b of the container 100 remain opaque.

In embodiments, the container 100 may change from clear to opaque, or opaque to clear, in a relatively short period of time. For example, where the container 100 turns clear upon being manipulated in the hand of technician, the container 100 may turn from opaque to clear in 3-4 seconds. Once no longer handled by the technician, the container may turn back from clear to opaque in 3-4 seconds. This length of time to change from one state to the other is a way of example only, and it may be shorter than 3 seconds and longer than 4 seconds in further embodiments.

In embodiments described above, when opaque, the thermochromic container 100 may block all of a selected wavelength of light from penetrating into container 100. In further embodiments, when opaque, the thermochromic container 100 may not block all, but may reduce the amount of the selected wavelength of light that penetrates into the container 100.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A container for holding a fluid, the container comprising:
a wall comprising a thermochromic material transmitting a wavelength of light to which the fluid is sensitive when the container is at a first temperature, and the thermochromic material blocking the wavelength of light when the container is at a second temperature.

2. The container of claim 1, wherein the wall is formed with the thermochromic material.

3. The container of claim 1, wherein the thermochromic material is applied as a film or ink onto the wall of the container.

4. The container of claim 1, wherein a temperature of the container changes from the second temperature to the first temperature upon being manipulated in a human hand.

5. The container of claim 1, wherein the first temperature is the temperature of a human hand.

6. The container of claim 1, wherein a temperature of the container changes from the second temperature to the first temperature upon being placed in a room which is at room temperature.

7. The container of claim 1, wherein the first temperature is room temperature.

8. The container of claim 1, wherein the entire container is at the first temperature, transmitting the wavelength of light, or at the second temperature, blocking the wavelength of light.

9. The container of claim 1, wherein a first portion of the container is at the first temperature, transmitting the wavelength of light, while a second portion of the container, different than the first portion, is at the second temperature, blocking the wavelength of light.

10. The container of claim 1, wherein the container is one of a centrifuge tube a micro-centrifuge tube and a pipette tip.

11. A container for holding a fluid, the container comprising:
a wall comprising a thermochromic material configured to allow visual inspection of the fluid within the container when the container is at a first temperature, and configured to block a wavelength of light to which the fluid is sensitive when the container is at a second temperature.

12. The container of claim 11, wherein the wavelength is in the visible light spectrum.

13. The container of claim 11, wherein the wavelength is ultraviolet light.

14. The container of claim 11, wherein the first temperature is the temperature of a human hand.

15. The container of claim 11, wherein the first temperature is room temperature.

16. A container for holding a fluid, the container comprising:
a wall comprising a thermochromic material configured to transmit a predefined wavelength of light to which the fluid is sensitive to allow visual inspection of the fluid within the container when the container is manipulated in a human hand to bring the container to a first temperature by manipulation of the container in a human hand, and the thermochromic material configured to block the wavelength of light to which the fluid is sensitive when the container is not at the first temperature.

17. The container of claim 16, wherein the wall is formed with the thermochromic material.

18. The container of claim 16, wherein the thermochromic material is applied as a film or ink onto the wall of the container.

19. A method of working with a fluid within a container in a laboratory, the fluid sensitive to a wavelength of light, the method comprising the steps of:
(a) controlling a temperature of the container to bring the container to a first temperature at which a thermochromic material of the container is clear;
(b) visually inspecting the fluid and/or an amount of fluid within the container while the container is controlled to be at the first temperature; and
(c) controlling a temperature of the container to bring the container to a second temperature at which the thermochromic material of the container is opaque to the wavelength of light to which the fluid is sensitive.

20. The container of claim 19, wherein the first temperature is the temperature of human skin, and said step (a) comprises controlling the temperature to be the first temperature by manipulating the container in a human hand.

21. The container of claim 20, wherein said step (c) comprises controlling the temperature to be the second temperature by not touching the container with the human hand.

22. The container of claim 19, wherein the first temperature is room temperature and said step (a) comprises controlling the temperature to be the first temperature by working with the container at room temperature.

23. The container of claim 22, wherein said step (c) comprises controlling the temperature to be the second temperature by cooling the container to a temperature below room temperature.
